(19) United States
(12) Patent Application Publication
(10) Pub. No.: US 2026/0029711 A1
(43) Pub. Date: Jan. 29, 2026

(54) ENHANCED EUV MATERIALS, PHOTORESISTS AND METHODS OF THEIR USE.

(71) Applicants: Alex P. G. Robinson, Birmingham (GB); Ed Jackson, Franklin, MA (US); Gregory O'Callaghan, Birmingham (GB); John Roth, Cohasset, MA (US); Alexandra McClelland, Worcester (GB); Tom Lada, Somerville, MA (US); Carmen Popescu, Birmingham (GB)

(72) Inventors: Alex P. G. Robinson, Birmingham (GB); Ed Jackson, Franklin, MA (US); Gregory O'Callaghan, Birmingham (GB); John Roth, Cohasset, MA (US); Alexandra McClelland, Worcester (GB); Tom Lada, Somerville, MA (US); Carmen Popescu, Birmingham (GB)

(73) Assignee: Irresistible Materials LTD, Birmingham, GB (GB)

(21) Appl. No.: 19/008,109

(22) PCT Filed: Jun. 24, 2023
(86) PCT No.: PCT/US2023/026171

§ 371 Date: Sep. 11, 2025

Related U.S. Application Data
(60) Provisional application No. 63/358,980, filed on Jul. 7, 2022.
(60) Provisional application No. 63/392,998, filed on Jul. 28, 2022.

(51) Int. Cl. G03F 7/004

(52) U.S. Cl. CPC G03F 7/0048; G03F 7/0045

(57) ABSTRACT

The current application discloses novel zwitterion materials which provide unexpected results useful in photolithographic resist compositions. In particular the compounds and photoresists made therefrom provide improvements in EUV photo defined line geometries as well as increased lithographic photospeed. Also provided are resist compositions containing the disclosed novel zwitterions.

### REFERENCE TO PRIOR FILED APPLICATIONS

The present application claims the benefit under 35 U.S.C. § 119, of U.S. Provisional Application Ser. No. 63/385,980 filed 7 Jul. 2022, entitled “ENHANCED EUV PHOTORESISTS AND METHODS OF THEIR USE’ and U.S. Provisional Application Ser. No. 63/392,998 filed 28 Jul. 2022, entitled, “ENHANCED EUV PHOTORESISTS AND METHODS OF THEIR USE”, which applications are incorporate herein in their entirety.

### FIELD OF INVENTION

The present application for patent discloses novel zwitterionic materials with improved sensitivity (photospeed), resolution (line width roughness) or both when formulated in EUV photoresists.

### BACKGROUND

Extreme ultraviolet lithography (EUVL) is one of the leading technology options to replace optical lithography for volume semiconductor manufacturing at feature sizes <20 nm. The extremely short wavelength (13.4 nm) is a key enabling factor for high resolution required at multiple technology generations. In addition, the overall system concept-scanning exposure, projection optics, mask format, and resist technology—is quite similar to that used for current optical technologies. Like previous lithography generations, EUVL consists of resist technology, exposure tool technology, and mask technology. The key challenges are EUV source power and throughput. Any improvement in EUV power source will directly impact the currently strict resist sensitivity specification. Indeed, a major issue in EUVL imaging is resist sensitivity, the lower the sensitivity, the greater the source power that is needed or the longer the exposure time that is required to fully expose the resist. The lower the power levels, the more noise affects the line edge roughness (LER) of the printed lines.

Various attempts have been made to alter the make-up of EUV photoresist compositions to improve performance of functional properties. Electronic device manufacturers continually seek increased resolution of a patterned photoresist image. It would be desirable to have new photoresist compositions that could provide enhanced imaging capabilities, including new photoresist compositions useful for EUVL.

As is well known, the manufacturing process of various kinds of electronic or semiconductor devices such as ICs, LSIs and the like involves fine patterning of a resist layer on the surface of a substrate material such as, for example, a semiconductor silicon wafer. This fine patterning process has traditionally been conducted by the photolithographic method in which the substrate surface is uniformly coated with a positive or negative tone photosensitive composition to form a thin layer and selectively irradiating with actinic rays (such as ultraviolet (UV), deep UV, vacuum UV, extreme UV, x-rays, electron beams and ion beams) via a transmission or reflecting mask followed by a development treatment to selectively dissolve away the coated photosensitive layer in the areas exposed or unexposed, respectively, to the actinic rays leaving a patterned resist layer on the substrate surface. The patterned resist layer, thus obtained, may be utilized as a mask in the subsequent treatment on the substrate surface such as etching. The fabrication of structure with dimensions of the order of nanometers is an area of considerable interest since it enables the realization of electronic and optical devices which exploit novel phenomena such as quantum confinement effects and also allows greater component packing density. As a result, the resist pattern is required to have an ever-increasing fineness which can be accomplished by using actinic rays having a shorter wavelength than the conventional ultraviolet light. Accordingly, it is now the case that, in place of the conventional ultraviolet light, electron beams (e-beams), excimer laser beams, EUV, BEUV and X-rays are used as the short wavelength actinic rays. The minimum size obtainable is, in part, determined by the performance of the resist material and, in part, the wavelength of the actinic rays. Various materials have been proposed as suitable resist materials. For example, in the case of negative tone resists based on polymer crosslinking, there is an inherent resolution limit of about 10 nm, which is the approximate radius of a single polymer molecule.

It is also known to apply a technique called “chemical amplification” to resist materials. A chemically amplified resist material is generally a multi-component formulation in which there is a matrix material, frequently a main polymeric component, such as a polyhydroxystyrene (PHOST) resin protected by acid labile groups and a photo acid generator (PAG), as well as one or more additional components which impart desired properties to the resist. The matrix material contributes toward properties such as etching resistance and mechanical stability. The chemical amplification occurs through a catalytic process involving the PAG, which results in a single irradiation event causing the transformation of multiple resist molecules. The acid produced by the PAG reacts catalytically with the polymer to cause it to lose a functional group or, alternatively, cause a crosslinking event. The speed of the reaction can be driven, for example, by heating the resist film. In this way the apparent sensitivity of the material to actinic radiation is greatly increased, as small numbers of irradiation events give rise to a large number of solubility changing events. As noted above, chemically amplified resists may be either positive or negative working. Thus, there is a continuing need for materials and compositions that provide access to finer and finer lines an spaces including improvements in pattern integrity such as, for example, reduction in line edge roughness, line width roughness and line wiggle.

### SUMMARY OF THE DISCLOSURE

Disclosed and claimed herein are novel materials which provide unexpected results for photolithographic patterns with geometries below 20 nm. In addition, line edge roughness, line width roughness and line wiggle are significantly reduced.

In a first embodiment, disclosed and claimed herein are compositions of matter comprising the chemical structure (I), (II), (III) and (IV):

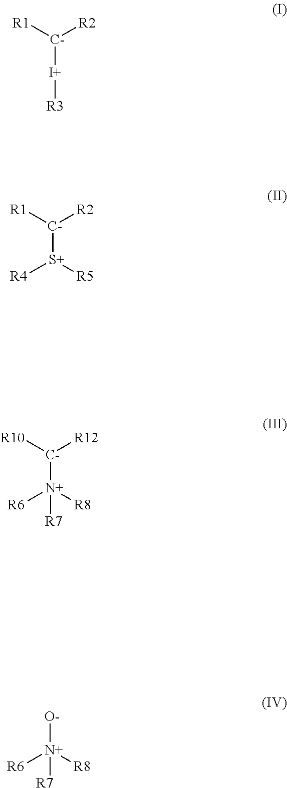

wherein R1, R2, R10 and R12 comprise esters, ketones or electron-withdrawing groups connected to a central carbon anion, R3 is a substituted or unsubstituted aromatic group, heterocyclic group, or fused aromatic group, wherein R4-R5 are the same or different, substituted or unsubstituted aromatic groups, heterocyclic groups, fused aromatic groups, alkyl groups, aralkyl groups, or wherein R4-R5 are joined to form a substituted or unsubstituted heterocycle, or fused heterocycle, wherein R6-R8 are the same or different, substituted or unsubstituted aromatic groups, heterocyclic groups, fused aromatic groups, alkyl groups, aralkyl groups, or wherein R6-R8 are joined to form a substituted or unsubstituted heterocycle, fused heterocycle, aromatic heterocycle, or fused heterocycle.

In a second embodiment, disclosed and claimed herein are compositions of matter of the above embodiment wherein R1, R2, R10 and R12 comprise ester groups, —(C═O)—O—R20, connected to the carbon anion wherein R20 is a substituted or unsubstituted phenyl group or heterocyclic group, a substituted or unsubstituted alkyl or alkenyl group.

In a third embodiment, disclosed and claimed herein are compositions of matter of any of the above embodiments wherein R20 comprises —CH₂—CH═CH—CH₂—Ph.

In a fourth embodiment, disclosed and claimed herein are compositions of matter of any of the above embodiments the substitution comprises an acid leaving labile group.

In a fifth embodiment, disclosed and claimed herein are compositions of matter of any of the above embodiments wherein the acid labile leaving group comprises a t-BOC group, an ester group, a ketal or acetal.

In a sixth embodiment, disclosed and claimed herein are compositions of matter of any of the above embodiments wherein R10 and R12 comprise a substitute or unsubstituted ring structure.

In a further embodiment, disclosed and claimed herein are compositions of matter of any of the above embodiments further comprising, in admixture a) at least one photoacid generators, b) at least one acid curable crosslinker and optionally at least one nucleophilic quencher.

In a further embodiment, disclosed and claimed herein are compositions of matter of any of the above embodiment wherein the photoresist is sensitive to ultraviolet (UV), deep UV, vacuum UV, extreme UV, x-rays, electron beams and ion beams.

As the requirement for feature size continues to be reduced, below 20 nm for example, there is a need to control the cationic polymerization and/or crosslinking, in negative working systems. Photoresists based on acid catalyzed deprotection such as in positive working systems, typically utilize base quenchers which control the migration of the many photogenerated acids to areas where deprotection is not desired. Epoxy-based negative working photoresist are initiated by photogenerated acid, but the active polymerization and crosslinking species is not a photoacid. It can readily be seen that after initial reaction of the epoxy, or other group, such as, for example, an oxetane, or an acid-labile protecting group, the continuation involves the photoacid protonation of the epoxy (or oxetane) oxygen to provide an epoxonium intermediate. However, after this initiating stage, the reaction continues by attack of the epoxonium intermediate by the oxygen of a neutral epoxy group. Propagation, polymerization and/or crosslinking then continues until termination. In these photopattern processes controlling the polymerization and/or crosslinking becomes important to prevent line growth, sharpening or line width reduction and polymer growth in areas which are undesirable. These problems include line edge roughness, line width reduction, line wiggle and other less than desirable pattern geometries. This concept is critical in line and space geometries less than 20 nm. Thus, any methods that will control the polymerization and/or crosslinking in photosystems, such as for example, EUV, is highly desirable.

Stable zwitterions useful in the current disclosure include, for example, zwitterions which contain a stable, internal carbanion associated with a positive charge elsewhere on the molecule. As used herein the term “stable internal anion” means the negatively charged region of the zwitterion.

Disclosed and claimed herein are photolithographic compositions containing at least one zwitterion as described.

As mentioned, base quenchers have been used in standard positive working systems where initiation and propagation are reliant on the photogenerated acid. In the negative systems of the current disclosure photogenerated acid function to initiate the curing process, while further polymerization and/or crosslinking does not depend on the acid. Base quenchers used for typical photolithographic systems only have a very limited effect in the currently presented systems which are required to generate line and space geometries below 20 nm.

The zwitterions of the current disclosure are incorporated into photoresists which contain photoacid generating components. Depending on the energy source, such as, for example, I-line (365 nm wavelength) or Extreme UV (EUV, 13 nm), the amount of acid generated per photo exposure will vary.

Not to be held to theory, it is believed that the zwitterion acts as an acid buffer in regions of high light/radiation intensity. The term buffering as used herein refers to the interaction of the stable anion additive with a photogenerated acid.

In exposures based on Extreme UV, where many H+ atoms are generated (via photoelectron generation) such buffering appears to improve the structure, definition and integrity of photolithographically created patterns.

In regions of high exposure, it is believed that the zwitterions of the photoresist react with the high levels of photogenerated acid. The remaining acid then reacts with the polymerization and/or crosslinking components of the resist. In this example, the epoxy polymerization and/or crosslinking components of the resist are the epoxy components.

In regions of low exposure or where there is acid migration, where low levels of photogenerated acid occurs, the stable internal anion of the zwitterion acts as a quencher, stopping the initiation and/or propagation of polymerization and/or crosslinking, from moving into unexposed regions preventing undesirable photopattern structures. In addition, the stable internal anions of the zwitterions act as acid scavengers in these low light systems.

Research has shown that the stable internal anions of the zwitterions in the photoresist, especially in EUV resists, of the current disclosure, increase contrast and reduce LER due to their buffering and quenching properties. Further we believe that the stable internal anions of the zwitterions of the current disclosure act as a quencher which stops polymerization of the photosensitive composition from migrating into unexposed areas.

In high light intensity regions, the stable anions of the zwitterions that have already been used as a buffer can no longer act as a quencher. Where the anion has already been used as a buffer, propagation or chain transfers (the mechanisms of polymerization) will proceed as is desired. The zwitterion may be acting as a very effective molecular switch.

Examples of synthesis of zwitterion compounds useful for the current disclosure can be found in U.S. Pat. Nos. 9,122,156, 9,229,322, and 9,519,215, all to Robinson, et al and in corporate herein by reference.

### DESCRIPTION OF FIGURES

FIG. 1 shows the structure of three sulfonium zwitterions disclosed and claimed in the current application.

FIGS. 2-3 show the structure of four iodonium zwitterions disclosed and claimed in the current application.

FIGS. 4-5 show the structure of six nitrogen cation zwitterions disclosed and claimed in the current application.

FIG. 6 shows the structure of the Control Compound X-2

FIG. 7 shows an SEM of the processed photoresist which contains a control, X-2, and an SEM of the processed photoresist of Compound I-1.

FIG. 8 shows an SEM of the processed photoresist which contains Compound S-1 and an SEM of the processed photoresist of Compound S-2.

FIG. 9 shows an SEM of the processed photoresist which contains Compound N-1.

FIG. 10 shows an SEM of the processed photoresist which contains a control, X-2, and an SEM of the processed photoresist of Compound S-3.

FIG. 11 shows an SEM of the processed photoresist which contains Compound N-3 and an SEM of the processed photoresist of Compound N-2.

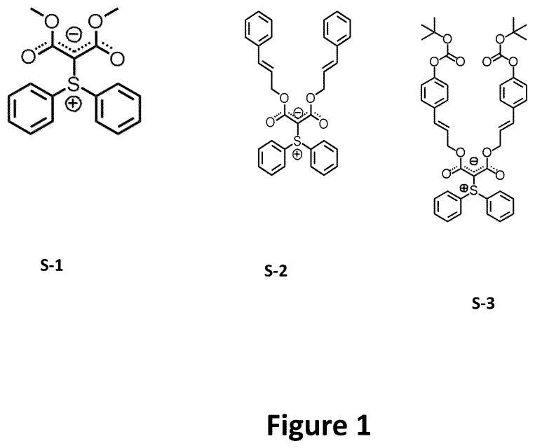

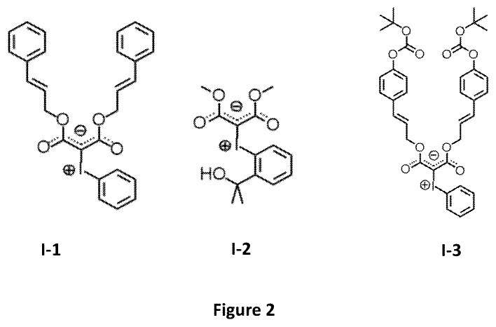

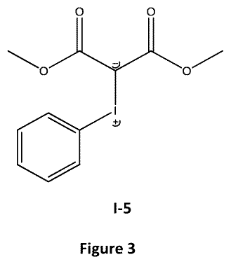

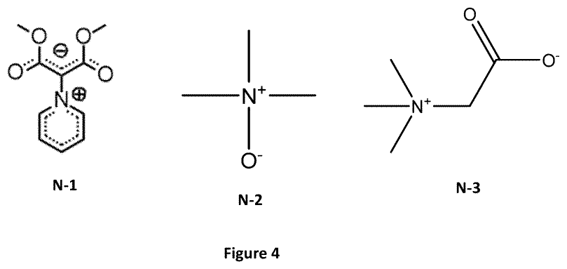

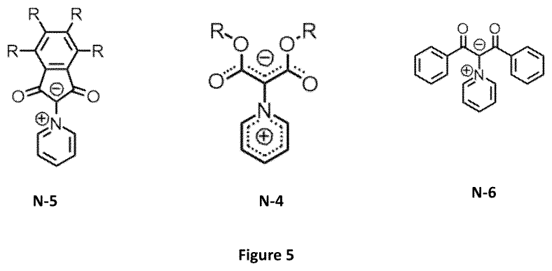

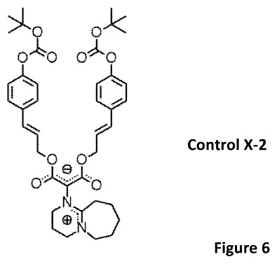

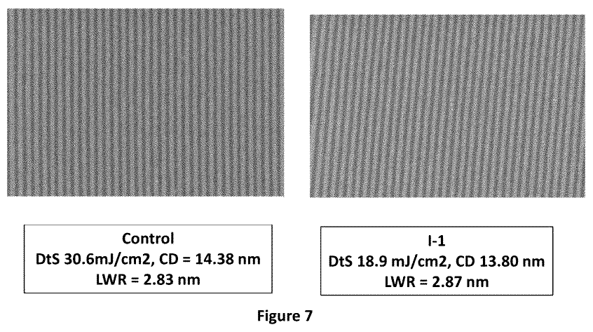

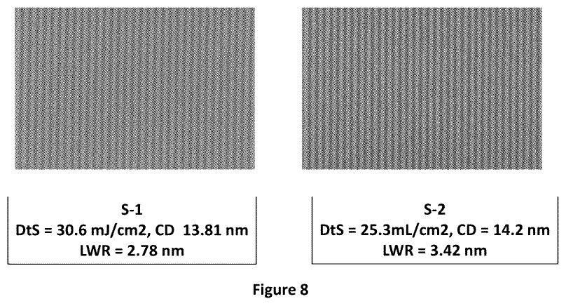

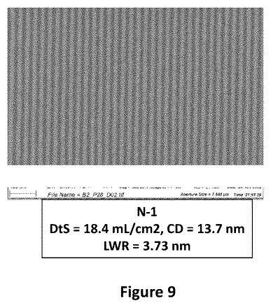

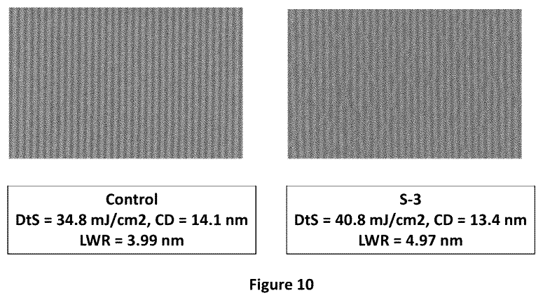

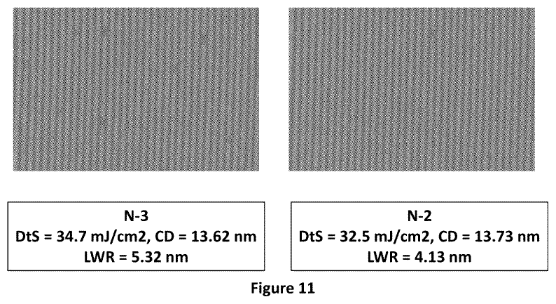

### DETAILED DESCRIPTION OF THE DISCLOSURE

As used herein, the conjunction “and” is intended to be inclusive and the conjunction “or” is not intended to be exclusive unless otherwise indicated or required by the context. For example, the phrase “or, alternatively” is intended to be exclusive. As used herein, the term “exemplary” is intended to describe an example and is not intended to indicate preference. As used herein, the term “energetically accessible” is used to describe products that may be thermodynamically or kinetically available via a chemical reaction.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

As used herein, the term “zwitterion” means a molecule which contains both a positive charge center and a negative charge center on the same molecule, either alpha to each other or spaced further in the molecule. Zwitterion, also called an inner salt, compounds are neutral compounds having formal unit electrical charges of opposite sign.

As used herein the term acid, proton and H+ are used interchangeably and refer to the acidic ion of a protic acid.

We have surprisingly found that the addition of certain, stable novel zwitterion materials to or negative resists, improve the geometries and integrity of lines and spaces after EUV exposure and processing, such as, for example, improvements in line edge roughness, line wiggle, line width roughness, undercutting, bridging, line collapse, and the like.

Disclosed and claimed herein are compositions of matter comprising a solvent and at least one compound of the chemical structure (I), (II), (III) and (IV) which contain a positive cationic center and a negatively charged substituent.

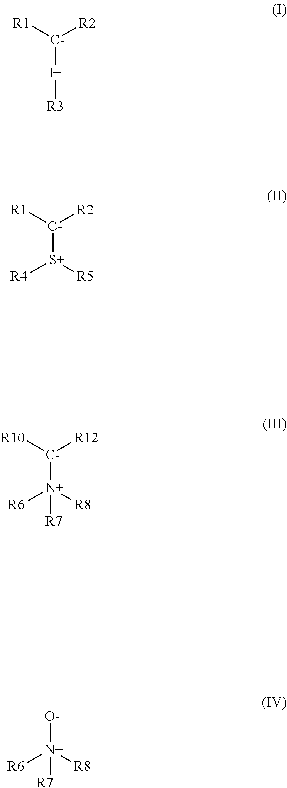

R1, R2, R10 and R 12 comprise esters, ketones or other electron-withdrawing groups connected to a central carbon anion. The electronic nature of the esters, ketone or other electron-withdrawing groups help to stabilize the negative charge of the carbon atom by charge delocalization over a number of atomic centers, such as, for example, unsaturations or other electron withdrawing and stabilizing functionalities. R1 and R2 may be esters giving ROOC—C⁻—COOR malonate materials, or R1 and R2 may be ketones giving ROC—C⁻—COR 1,3 diketones. When the cationic center is Iodonium (I) one other substituent is bonded to the Iodine. Here R3 can be, for example, substituted or unsubstituted aromatic group, heterocyclic group, or fused aromatic group. When the cationic center is sulfonium (II) there can be two substituents bonded to the sulfur. Here R4-R5 are the same or different, substituted or unsubstituted aromatic groups, heterocyclic groups, fused aromatic groups, alkyl groups, or aralkyl groups. R4-R5 may be part of a sulfur ring system such as, for example, a substituted or unsubstituted heterocycle, or fused heterocycle, a thiophene, a thiazole, and the like. When the cationic center is a nitrogen (III) R6-R8 are the same or different, substituted or unsubstituted aromatic groups, heterocyclic groups, fused aromatic groups, alkyl groups, aralkyl groups. R6-R8 may be part of a nitrogen ring system such as, for example, a substituted or unsubstituted heterocycle, fused heterocycle, pyrrole, pyridine, imidazole, pyrazole, pyrazine, pyrimidine, pyridazine, 1,2,3-triazole, 1,2,4-triazole, 1,3,5-triazine, 1,2,4-triazine, tetrazole and the like, including nitrogen heterocycles that also contain a non-nitrogen atom, such as for example, an oxygen, sulfur, and the like. In addition when the cationic center is nitrogen, the carbon anion may be replaced by an oxygen anion (IV). R6, R7 and R8 are as defined above.

Further disclosed and claimed herein are compositions of matter of the above embodiment wherein R1, R2, R10 and R12 comprise ester groups, —(C═O)—O—R20, connected to the carbon anion and R20 is a substituted or unsubstituted phenyl group or heterocyclic group, a substituted or unsubstituted alkyl or alkenyl group, such as for example —CH₂—CH═CH—CH₂—Ph.

Further disclosed and claimed herein are compositions of matter of any of the above embodiments comprising an acid leaving labile group attached to the ester constituent. The acid labile leaving group may comprise, for example, a t-BOC group, an alkyl-carbonate group, an ester group, a ketal or acetal.

Further disclosed and claimed herein are compositions of matter of any of the above embodiments wherein R10 and R12 comprise a substitute or unsubstituted ring structure, such as for example, a cycloalkyl group, an aromatic group, a fused aromatic group, a heterocyclic group, a fused heterocyclic group, an aralkyl group and the like,

Further disclosed and claimed herein are compositions of matter of any of the above embodiments further comprising, in admixture a) at least one photoacid generators, b) at least one acid curable crosslinker and optionally, c) at least one nucleophilic quencher. Quenchers useful in the current disclosure include, for example, onium sulfonate, such as triphenylsulfonium tosylates, triflates, nonaflates, dipheniodonium camphorsulfonate) and the like.

Further disclosed and claimed herein are compositions of matter of any of the above embodiments wherein the photoacid generators may include onium salt compounds, such as sulfonium salts, phosphonium salts or iodonium salts, sulfone imide compounds, halogen-containing compounds, sulfone compounds, ester sulfonate compounds, quinone diazide compounds, diazomethane compounds, dicarboximidyl sulfonic acid esters, ylideneaminooxy sulfonic acid esters, sulfanyldiazomethanes, or a mixture thereof.

The at least one crosslinker comprises an acid sensitive monomer or polymer, wherein the at least one crosslinker comprises at least one of a glycidyl ether, glycidyl ester, glycidyl amine, a methoxymethyl group, an ethoxy methyl group, a butoxymethyl group, a benzyloxymethyl group, dimethylamino methyl group, diethylamino methyl group, a dibutoxymethyl group, a dimethylol amino methyl group, diethylol amino methyl group, a dibutylol amino methyl group, a morpholino methyl group, acetoxymethyl group, benzyloxy methyl group, formyl group, acetyl group, vinyl group or an isopropenyl group or other acid sensitive (reactive) crosslinker well known in the art.

Further disclosed and claimed herein are compositions of matter of any of the above embodiment wherein the solvent can be, for example, at least one of ethers, esters, etheresters, alcohols, ketones, cyclic ketones, ketoneesters ethylene glycol monoalkyl ethers, diethylene glycol dialkyl ethers, propylene glycol monoalkyl ethers, propylene glycol dialkyl ethers, alkyl phenyl ethers, anisole, acetate esters, hydroxyacetate esters, lactate esters, and halogenated solvent or other solvents well known in the art.

Examples of photoacid generators, crosslinkers and solvents useful for the current disclosure can be found in U.S. Pat. No. 9,519,215B2 to A. P. G. Robinson, et al incorporated by reference herein in their entirety.

Further disclosed and claimed herein are compositions of matter of any of the above embodiment wherein the materials and photoresist compositions are sensitive to ultraviolet (UV), deep UV, vacuum UV, extreme UV, x-rays, electron beams and ion beams.

It should be noted that many of the novel compounds disclosed and claimed herein are photosensitive as they are comprised of sulfonium functionalities which are well known to react with many categories of actinic radiation to generate acid, free radicals and/or other reactive decomposition products. As well the iodonium salts disclosed and claimed herein are also known to be photosensitive in the same ways as the sulfonium compounds claimed herein. These compounds could be expected to either stand alone in actinic radiation photosensitive compositions, such as, for example, photoresists, or to aid in synergy with photoacid generators typically found in photosensitive compositions currently available.

### EXPERIMENTAL

### Below are Representative Examples of the Zwitterions Useful in the Current Disclosure

Compounds N-2 and N-3 were obtained from Sigma-Aldrich.

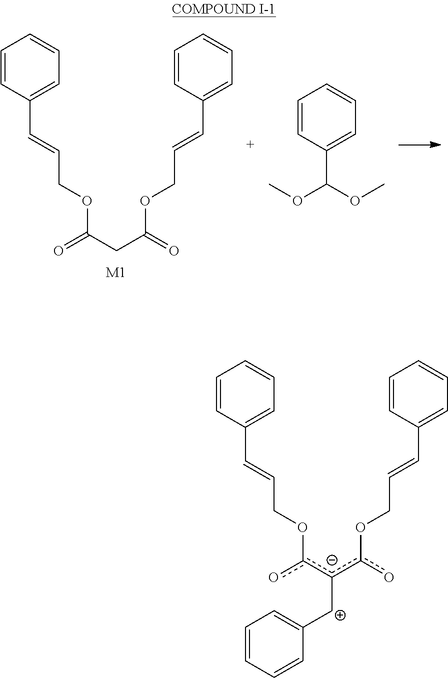

Potassium hydroxide (0.50 g, 8.92 mmol, 6.00 eq) and M1 were added to a 100 mL round bottom flask. The flask was pump purged three times with inert gas and vacuum. 5 mL anhydrous acetonitrile was added and the mixture was stirred in an ice bath for 15 minutes. (diacetoxyiodo) benzene (0.53 g, 1.64 mmol, 1.10 eq) was added via a total of 10 mL acetonitrile. The reaction was stirred for 2 hours, adding ice to the bath to maintain a temperature of 0° C. 6 mL of cold water was added and the reaction mixture was filtered. The solids were washed 2× with 3 mL cold water followed by 6 mL diethyl ether. The product was dried at 25° C. overnight (0.383 g, 47% yield). The product was evaluated by 1H NMR.

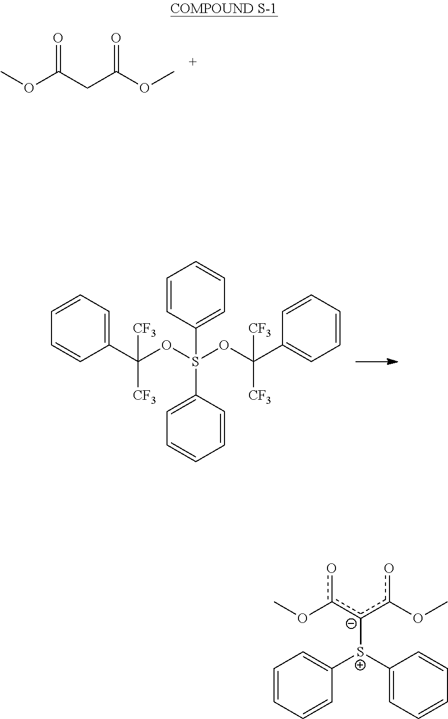

Bis[(1,1,1,3,3,3-hexafluoro-2-phenylpropan-2-yl)oxy]diphenyl-λ4-sulfane (Martin's sulfurane, 3.82 g, 5.68 mmol, 1.50 eq) and dimethyl malonate (0.50 g, 3.78 mmol, 1.00 eq) were added to a 100 mL round bottom flask. The flask was pump purged three times with inert gas and vacuum. 38 mL anhydrous diethyl ether was added and the reaction was stirred overnight under nitrogen. The reaction mixture was concentrated to dryness by rotary evaporation and the product was purified via silica gel chromatography using 4:1 ethyl acetate: hexane. The product was collected and solvent was removed to give a white solid that was dried overnight at 30° C. under vacuum (1.187 g, 94% yield). The product was evaluated by 1H NMR.

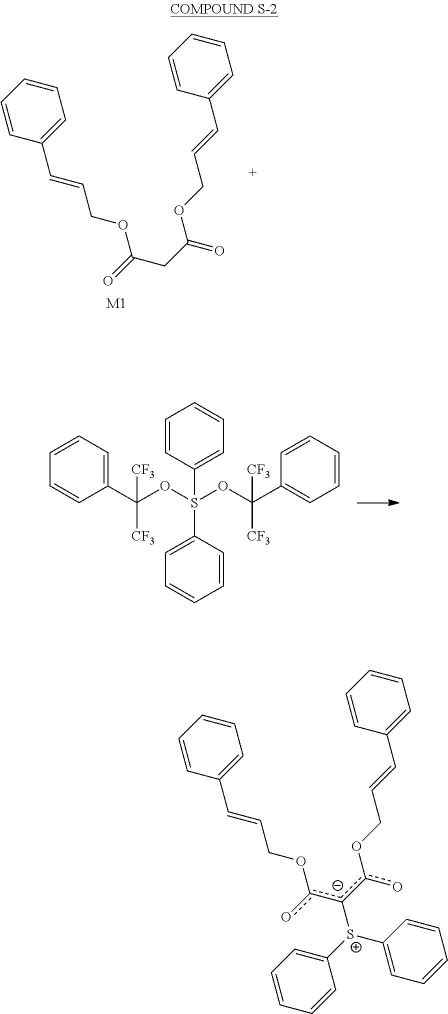

Bis[(1,1,1,3,3,3-hexafluoro-2-phenylpropan-2-yl)oxy]diphenyl-λ4-sulfane (Martin's sulfurane, 13.80 g, 20.51 mmol, 1.50 eq) and M1 (4.60 g, 13.68 mmol, 1.00 eq) were added to a 250 mL round bottom flask. The flask was pump purged three times with inert gas and vacuum. 137 mL anhydrous diethyl ether was added and the reaction was stirred overnight under nitrogen. The reaction mixture was concentrated to dryness by rotary evaporation and the product was purified via silica gel chromatography using 4:1 ethyl acetate: hexane. The product was collected and solvent was removed to give a white solid that was dried overnight at 30° C. under vacuum (5.45 g, 76% yield). The product was evaluated by 1H NMR.

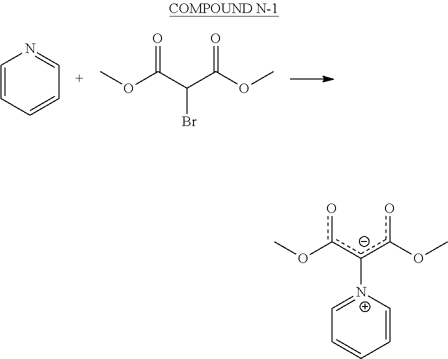

Pyridine (12.10 mL, 149.76 mmol, 15.80 eq) was added to a 100 mL round bottom flask. Dimethyl bromomalonate (1.24 mL, 9.48 mmol, 1.00 eq) was added while stirring over a period of 10 minutes using a syringe pump. The solution was stirred overnight under nitrogen. Triethylamine (1.94 mL, 13.93 mmol, 1.47 eq) was added to the reaction and it was stirred for an additional 5 hours. Ethyl acetate (50 mL) was added and the mixture was filtered. The solids were washed with 50 mL toluene. The filtrate was then purified via silica gel chromatography using 1:1 ethyl acetate: isopropanol. The product was collected and solvent was removed to give a yellow solid that was dried overnight at 35° C. under vacuum (0.36 g, 18% yield). The product was evaluated by 1H NMR.

### FORMULATIONS

General formulation: The formulation below is a general formulation in which the materials of the current disclosure were used for testing. The molar ratios were maintained when materials were tested which had different molecular weights. Techniques to remove metal content are well known in the literature.

It was also found that 2 or more zwitterion materials, including different isomers of the current disclosure could be combined in various proportions to obtain a combination to form a blend of properties of those blended zwitterions.

The percent solids in the formulation may be altered to obtain a film thickness of 20 nm when spun and dried.

### Formulation 1

All amounts of materials in the formulation are given in Molar Equivalents (ME) to keep the exact ratio of materials constant, as the molecular weights of the materials may vary.

536 mL of ethyl lactate, 0.095 ME of the compound to be tested, see below, and 1.00 ME of crosslinker (CL02 below) were admixed via sonication. The admixture was pushed through a pre-conditioned metal ion removal filter stack at 6 psi by way of a canula from the one-neck round bottom flask. To 500 mL of the admixture was added 0.455 ME of PAG02, below, and 0.174 ME of nucleophilic quencher Q02, below, and mixed until completely dissolved at a concentration of 16.5 g/L. The formulation was filtered through a 0.2 μm PTFE filter and kept protected from light and held at 5° C. until use.

### Formulation 2

536 mL of ethyl lactate, 0.063 ME of the compound to be tested, see below, and 1.00 ME of crosslinker (CL02 below) were admixed via sonication. The admixture was pushed through a pre-conditioned metal ion removal filter stack at 6 psi by way of a canula from the one-neck round bottom flask. To 500 mL of the admixture was added 0.455 ME of PAG02, below, and 0.077 ME of nucleophilic quencher Q02, below, and mixed until completely dissolved at a concentration of 15 g/L. The formulation was filtered through a 0.2 μm PTFE filter and kept protected from light and held at 5° C. until use.

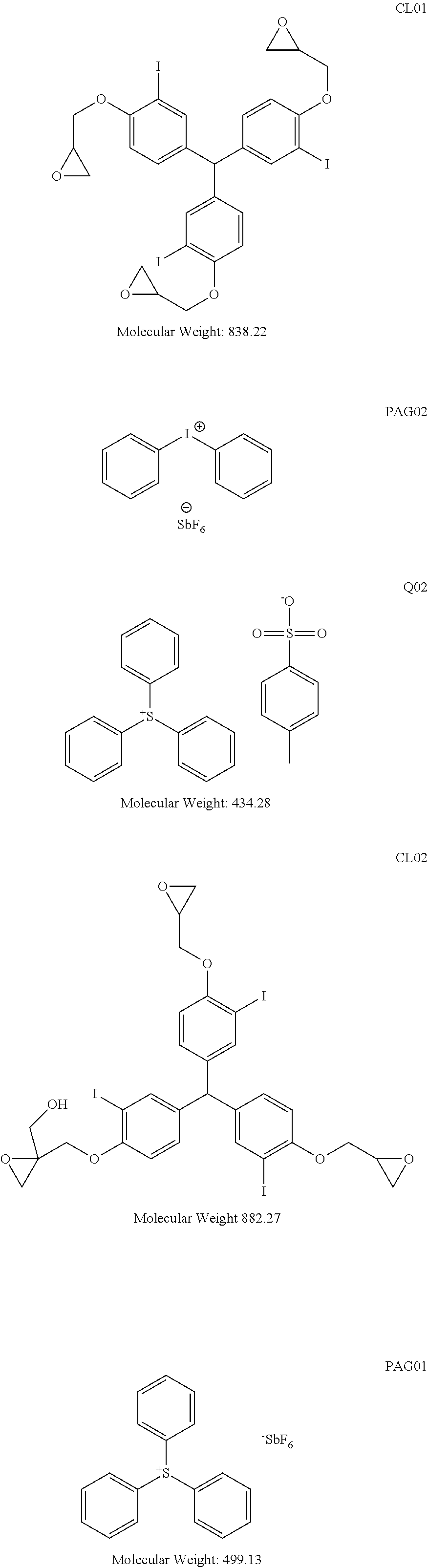

### TESTING OF FORMULATIONS

Note: The formulations are prepared at such concentration to obtain a 20 nm film thickness when spun at 1500-2500 rpm and dried. The film thicknesses are measured using ellipsometry optical techniques.

A silicon wafer was spin coated at 2000 rpm using Brewer Science Optistack AL 212 underlayer and baked at 205° C. for 30 sec. The resist formulation was dispensed using a pipette onto the wafer and spun at the spin speed required to get a 20 nm film thickness target, generally 1200-2300 rpm. The wafer was baked at 60 C for 3 minutes and checked that the film is still appropriate for exposure (e.g. no dewetting). The wafer was exposed using a non-contact mask using the PSI synchrotron, the mask contains patterns at pitch 44 nm line spaces and a number of die are exposed on one wafer with increasing dosages. The wafers may optionally be subjected to a post exposure bake for 1-2 minutes, generally at 60°-80° C. The wafer was immersion developed in nBA (n-butyl acetate) for 30-60 seconds and then, optionally, have a 15 second rinse in MIBC (methyl isobutyl carbinol)

The patterns were then inspected using a SEM and images were taken through dose.

The line widths and line width roughness were measured using a software package called SMILE. The line widths and LWR were plotted against dose, trendlines are calculated, and the dose required to achieve 22 nm lines is calculated from this plot; and the LWR at 22 nm lines is also recorded.
Critical Dimension (CD) in nanometers
Sensitivity (DtS-dose to size) in mJ/cm²
Line Width Roughness (LWR) in nanometers
Line Edge Roughness (LER) in nanometers

Chart 1, below, shows the results of the photolithographic process described herein. The chart lists in the first column the example compounds disclosed herein and used in the formulation described. Column 2 shows the dose to size (DtS) of the energy in mJ/cm² needed to obtain the desired line/space geometry using the lithographic mask used. Column 3 shows the line edge roughness (LER) in nm of the obtained lines. Column 4 shows the line width roughness in nm of the obtained spaces. Column 5 shows the critical dimensions (CD) in nm of the photoresist compositions. Column 6 indicates the formulation used.

CHART 1

| | DtS | LWR | LER | CD | |
|---|---|---|---|---|---|
| Compound | (mJ/cm2) | (nm) | (nm) | (nm) | Formulation |
| Control X-2 | 27.68 | 3.50 | 2.72 | 14.38 | 1 |
| I-1 | 19.34 | 3.64 | 2.49 | 13.80 | 1 |
| S-1 | 30.14 | 3.03 | 2.12 | 13.81 | 1 |
| S-2 | 25.49 | 2.71 | 2.45 | 14.02 | 1 |
| S-3 | 38.90 | 5.40 | 4.57 | 13.54 | 1 |

It can be seen from the above data that I-1 shows a major improvement in photospeed compared to the control and other compounds tested. This result may be due to the fact that I-1 may mimic a photoacid generator by virtue of its iodonium configuration.

S-1 and S-2 both showed improvements in LER and LWR showing excellent reproduction of the target mask.

CHART 2

| | DtS | LWR | LER | CD | |
|---|---|---|---|---|---|
| Compound | (mJ/cm2) | (nm) | (nm) | (nm) | Formulation |
| Control X-2 | 31.85 | 4.00 | 2.82 | 14.57 | 2 |
| N-1 | 18.40 | 3.73 | 2.74 | 13.71 | 1 |
| N-3 | 32.29 | 4.29 | 3.18 | 13.62 | 2 |
| N-2 | 32.50 | 3.89 | 2.84 | 13.73 | 2 |

Chart 2 compares the cationic-nitrogen zwitterion to the control. It can be seen that N-1 shows a major increase in photospeed compared to the control and other compounds in the study while the LER and LWR were slightly improved over X-2 and N-3.

The results show that a variety of very specific zwitterions exhibit major improvements in line width roughness, line edge roughness or photospeed or a combination of the three when used in EUV photoresists. Thus the novel compounds of the current disclosure and the unexpected obtain from them provide for major advancements in microlithography and hence next generation nanotechnology.

We claim:

1. A photoresist composition of matter comprising a solvent and at least one of a zwitterion having a chemical structure chosen from (I), (II), (III) or (IV): 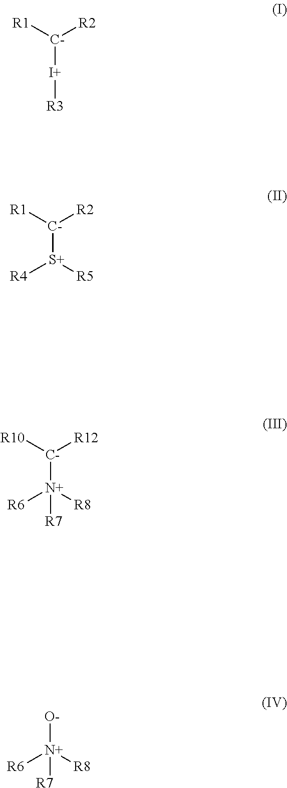
wherein R1, R2, R10 and R12 comprise esters, ketones or electron-withdrawing groups connected to a central carbon anion, R3 is a substituted or unsubstituted aromatic group, heterocyclic group, or fused aromatic group, wherein R4-R5 are the same or different, substituted or unsubstituted aromatic groups, heterocyclic groups, fused aromatic groups, alkyl groups, aralkyl groups, or wherein R4-R5 are joined to form a substitute or unsubstituted heterocycle, or fused heterocycle, wherein R6-R8 are the same or different, substituted or unsubstituted aromatic groups, heterocyclic groups, fused aromatic groups, alkyl groups, aralkyl groups, or wherein R6-R8 are joined to form a substitute or unsubstituted heterocycle, fused heterocycle, aromatic heterocycle, or fused heterocycle.

2. The composition of matter of claim 1, wherein R1, R2, R10 and R12 comprise ester groups, —(C═O)—O—R20, connected to the carbon anion wherein R20 is a substituted or unsubstituted phenyl group or heterocyclic group, a substituted or unsubstituted alkyl or alkenyl group.

3. The composition of claim 2, wherein R20 comprises —CH₂—CH═CH—Ph.

4. The composition of claim 2, wherein the substitution comprises an acid labile leaving group.

5. The composition of claim 3, wherein the acid labile leaving group comprises an alkyl-oxycarbonyl group, an ester group, a ketal or acetal.

6. The composition of claim 1, wherein R10 and R12 comprise a substituted or unsubstituted ring structure.

7. The composition of claim 1, wherein the solvent comprises at least one of ethers, esters, etheresters, alcohols, ketones, ketoneesters ethylene glycol monoalkyl ethers, diethylene glycol dialkyl ethers, propylene glycol monoalkyl ethers, propylene glycol dialkyl ethers, alkyl phenyl ethers, anisole, acetate esters, hydroxyacetate esters, lactate esters, and halogenated solvent.

8. The composition of matter of claim 1, further comprising, in admixture a) at least one photoacid generators, b) at least one acid curable crosslinker and c) at least one nucleophilic quencher.

9. The composition of claim 7, wherein R1, R2, R10 and R12 comprise ester groups, —(C═O)—O—R20, connected to the carbon anion wherein R20 is a substituted or unsubstituted phenyl group or heterocyclic group, a substituted or unsubstituted alkyl or alkenyl group.

10. The composition of claim 8, wherein R20 comprises —CH₂—CH═CH—Ph.

11. The composition of claim 8, wherein the substitution comprises an acid labile leaving group.

12. The composition of claim 9, wherein the acid labile leaving group comprises an alkyl-carbonate group, an ester group, a ketal or acetal.

13. The composition of claim 7, wherein R10 and R12 comprise a substituted or unsubstituted ring structure.

14. The composition of claim 7, wherein the at least one photoacid generator is chosen from a sulfonium salt, an iodonium salt, a sulfone imide, a halogen-containing compound, a sulfone compound, an ester sulfonate compound, a diazomethane compound, a dicarboximidyl sulfonic acid ester, an ylideneaminooxy sulfonic acid ester, a sulfanyldiazomethane, or a mixture thereof.

15. The composition of claim 7, wherein the at least one crosslinker comprises an acid sensitive monomer or polymer, and wherein the at least one crosslinker comprises at least one of a glycidyl ether, glycidyl ester, glycidyl amine, a methoxymethyl group, an ethoxy methyl group, a butoxymethyl group, a benzyloxymethyl group, dimethylamino methyl group, diethylamino methyl group, a dibutoxymethyl group, a dimethylol amino methyl group, diethylol amino methyl group, a dibutylol amino methyl group, a morpholino methyl group, acetoxymethyl group, benzyloxy methyl group, formyl group, acetyl group, vinyl group or an isopropenyl group.

16. The composition of claim 7, wherein the nucleophilic quencher comprises one or more triphenylsulfonium sulfonates or diphenyl iodonium sulfonates.

17. The composition of claim 7, wherein the photoresist is sensitive to ultraviolet (UV), deep UV, vacuum UV, extreme UV, x-rays, electron beams and ion beams.
